(19) United States
(12) Patent Application Publication
(10) Pub. No.: US 2021/0183685 A1
(43) Pub. Date: Jun. 17, 2021

(54) EDGE RING AND SUBSTRATE PROCESSING APPARATUS

(71) Applicant: TOKYO ELECTRON LIMITED, Tokyo (JP)

(72) Inventors: Sungjae LEE, Gyeonggi-do (KR); Toshiya TSUKAHARA, Miyagi (JP); Mitsuaki SATO, Miyagi (JP); Tetsuji SATO, Miyagi (JP)

(73) Assignee: TOKYO ELECTRON LIMITED, Tokyo (JP)

(21) Appl. No.: 17/124,139

(22) Filed: Dec. 16, 2020

(30) Foreign Application Priority Data
Dec. 16, 2019 (JP) 2019-226533

(51) Int. Cl. H01L 21/687; H01L 21/683; H01L 21/67; H01J 37/32

(52) U.S. Cl. CPC H01L 21/68735; H01L 21/68757; H01L 21/6831; H01J 2237/334; H01J 37/32642; H01J 37/32715; H01L 21/67069

(57) ABSTRACT

Provided is an edge ring to reduce the frequency of replacement of an edge ring used for plasma processing and to suppress the leakage of a heat transfer gas. The edge ring has an annular first member and an annular second member, the first member has a recess on the lower surface and is made of a first material having plasma resistance, and the second member is arranged in the recess of the first member and is made of a second material having a rigidity lower than that of the first material.

### CROSS-REFERENCE TO RELATED APPLICATIONS

This application claims the benefit of Japanese Patent Application No. 2019-226533 filed on Dec. 16, 2019, the entire disclosures of which are incorporated herein by reference.

### TECHNICAL FIELD

The present disclosure relates to an edge ring and a substrate processing apparatus.

### BACKGROUND

In plasma processing on a substrate, an edge ring may be arranged along the outer periphery of the substrate arranged in a chamber having a predetermined degree of vacuum. By arranging the edge ring, the plasma processing can be performed uniformly across the surface of the substrate.

In addition, the plasma processing on the substrate is performed in a state where the substrate and the edge ring mounted on an electrostatic chuck are adsorbed to the electrostatic chuck by an electrostatic attraction force. Furthermore, to improve heat transfer between the substrate and the electrostatic chuck and heat transfer between the edge ring and the electrostatic chuck, a heat transfer gas such as He gas is supplied to a space between the electrostatic chuck and the substrate and to a space between the electrostatic chuck and the edge ring.

In the related art, an edge ring made of silicon carbide (SiC) (hereinafter, sometimes referred to as an “SiC edge ring”) is known. Due to high plasma resistance of the SiC edge ring, the frequency of replacement of the edge ring can be reduced.

Examples of related art include JP-A-2010-251723.

### SUMMARY

The disclosure is directed to an edge ring that is replaced less frequently and capable of suppressing leakage of a heat transfer gas.

The edge ring according to an aspect of the disclosure has an annular first member and an annular second member. The first member has a recess on a lower surface and is made of a first material having plasma resistance. The second member is arranged in the recess of the first member and is made of a second material having a rigidity lower than that of the first material.

Using the edge ring according to the disclosure for the plasma processing reduces the frequency of replacement of the edge ring and suppresses the leakage of a heat transfer gas.

### BRIEF DESCRIPTION OF THE DRAWINGS

FIG. 1 is a diagram illustrating a configuration example of a substrate processing apparatus;

FIG. 2 is a diagram illustrating an example of an edge ring and a wafer; and

FIG. 3 is a diagram illustrating a configuration example of the edge ring.

### DETAILED DESCRIPTION

Hereinafter, embodiments of the technique of the disclosure will be described with reference to the drawings. In the following embodiments, the same components are designated by the same reference numerals.

<Configuration of Substrate Processing Apparatus>

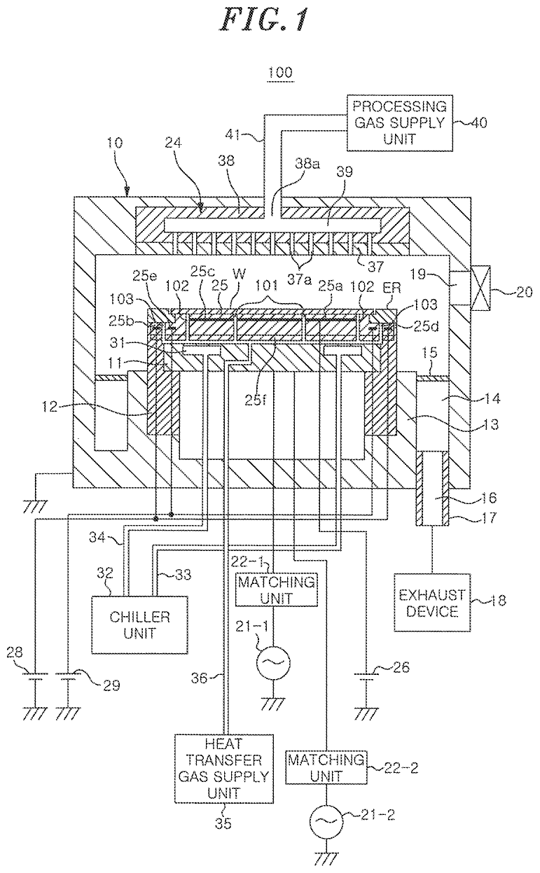

In FIG. 1, a substrate processing apparatus 100 has a chamber 10 made of, for example, aluminum or stainless steel. The chamber 10 is grounded for safety.

A disc-shaped susceptor 11 is horizontally arranged in the chamber 10. The susceptor 11 is arranged on a lower surface of an electrostatic chuck 25 on which a semiconductor substrate (hereinafter, also referred to as a “wafer W” in some cases) as a substrate to be processed and an edge ring ER are mounted. In addition, the susceptor 11 also functions as a lower electrode to which a radio frequency (RF) power is supplied. The susceptor 11 is made of, for example, aluminum and is supported by a cylindrical support portion 13 extending vertically upwards from the bottom of the chamber 10 via an insulating cylindrical holding member 12.

An exhaust passage 14 is formed between the side wall of the chamber 10 and the cylindrical support portion 13, an annular baffle plate 15 is arranged at the inlet or midway of the exhaust passage 14, an exhaust port 16 is provided at the bottom of the chamber 10, and an exhaust device 18 is connected to the exhaust port 16 via an exhaust pipe 17. The exhaust device 18 has a vacuum pump and decompresses a processing space provided by the chamber 10 to a predetermined degree of vacuum. In addition, the exhaust pipe 17 has an automatic pressure control valve (APC), which automatically controls the pressure inside the chamber 10. Moreover, a gate valve 20 that opens and closes a loading/unloading port 19 for the wafer W is provided to the side wall of the chamber 10.

Radio frequency power supplies 21-1 and 21-2 are electrically coupled to the susceptor 11 via matching units 22-1 and 22-2. The radio frequency power supply 21-1 supplies a radio frequency power to the susceptor 11 for plasma generation. It is preferable that the radio frequency power supply 21-1 supplies a radio frequency power of 27 to 100 MHz to the susceptor 11 and supplies a radio frequency power of, for example, 40 MHz to the susceptor 11. In addition, the radio frequency power supply 21-2 supplies a radio frequency power to the susceptor 11 to attract ions to the wafer W. It is preferable that the radio frequency power supply 21-2 supplies a radio frequency power of 400 KHZ to 40 MHz to the susceptor 11 and supplies a radio frequency power of, for example, 3 MHz to the susceptor 11. The matching unit 22-1 matches the output impedance of the radio frequency power supply 21-1 with the input impedance of the susceptor 11 side, and the matching unit 22-2 matches the output impedance of the radio frequency power supply 21-2 with the input impedance of the susceptor 11 side.

A shower head 24 as an upper electrode having a ground potential is arranged on the ceiling of the chamber 10.

The electrostatic chuck 25 arranged on the upper surface of the susceptor 11 attracts the wafer W and the edge ring ER mounted on the electrostatic chuck 25 by an electrostatic attraction force. The electrostatic chuck 25 has a disc-shaped central portion 25a, an annular outer peripheral portion 25b, and a disc-shaped base portion 25f having a diameter larger than that of the central portion 25a, and the central portion 25a projects upwards with respect to the outer peripheral portion 25b. The lower surfaces of the central portion 25a and the outer peripheral portion 25b and the upper surface of the base portion 25f are adhered to each other to form the electrostatic chuck 25. A wafer W is mounted on the upper surface of the central portion 25a, and an edge ring ER that annularly surrounds the central portion 25a is mounted on the upper surface of the outer peripheral portion 25b. In addition, the central portion 25a is formed by interposing an electrode plate 25c configured with a conductive film between a pair of dielectric films, while the outer peripheral portion 25b is formed by interposing electrode plates 25d and 25e configured with a conductive film between a pair of dielectric films. That is, the electrode plates 25c, 25d, and 25e are provided inside the electrostatic chuck 25. The electrode plate 25c is provided in a region corresponding to the wafer W inside the electrostatic chuck 25. The electrode plates 25d and 25e are provided in a region corresponding to the edge ring ER inside the electrostatic chuck 25. A DC power supply 26 is electrically connected to the electrode plate 25c. A DC power supply 28 is electrically connected to the electrode plate 25d. A DC power supply 29 is electrically connected to the electrode plate 25e. Then, the electrostatic chuck 25 attracts and holds the wafer W by the Coulomb force or the Johnson-Rahbek force generated by the DC voltage applied to the electrode plate 25c from the DC power supply 26. The electrostatic chuck 25 attracts and holds the edge ring ER by the Coulomb force or the Johnson-Rahbek force generated by the DC voltage applied to the electrode plates 25d and 25e from the DC power supplies 28 and 29. That is, in a case where FIG. 1 is viewed in plan view, inside the electrostatic chuck 25, an electrode (first electrode) that electrostatically attracts the wafer W is provided such that the first electrode at least partially overlaps with the wafer W. An electrode (second electrode) that electrostatically attracts the edge ring ER is provided such that the second electrode at least partially overlaps with the edge ring ER. The second electrode may include two or more electrode parts.

As described above, the wafer W is mounted on the upper surface of the central portion 25a of the electrostatic chuck 25, and the edge ring ER that annularly surrounds the central portion 25a is mounted on the upper surface of the outer peripheral portion 25b of the electrostatic chuck 25. That is, the edge ring ER is arranged on the electrostatic chuck 25 so as to surround the periphery of the wafer W. In addition, the lower surface of the electrostatic chuck 25 and the upper surface of the susceptor 11 are in contact with each other. Therefore, the susceptor 11 and the electrostatic chuck 25 are formed as a stage on which the wafer W and the edge ring ER are mounted.

An annular cooling medium chamber 31 extending in the circumferential direction is provided inside the susceptor 11. A cooling medium (for example, cooling water) having a predetermined temperature is circulated and supplied to the cooling medium chamber 31 via pipes 33 and 34 from a chiller unit 32, and the processing temperature of the wafer W on the electrostatic chuck 25 is controlled by the temperature of the cooling medium.

Furthermore, the heat transfer gas (for example, He gas) from a heat transfer gas supply unit 35 is supplied to a space between the upper surface of the electrostatic chuck 25 and the lower surface of the wafer W and to a space between the upper surface of the electrostatic chuck 25 and the lower surface of the edge ring ER via a gas supply pipe 36 and gas introduction holes 101, 102, and 103. The gas supply pipe 36 is arranged to penetrate the susceptor 11 and the base portion 25f of the electrostatic chuck 25. In addition, the gas introduction holes 101 and 102 connected to the gas supply pipe 36 are provided in the central portion 25a of the electrostatic chuck 25, and the gas introduction hole 103 connected to the gas supply pipe 36 is provided in the outer peripheral portion 25b of the electrostatic chuck 25. In the outer peripheral portion 25b of the electrostatic chuck 25, the two electrode plates of the electrode plate 25d and the electrode plate 25e are arranged with the gas introduction hole 103 interposed between the electrode plate 25d and the electrode plate 25e. The heat transfer gas supplied from the heat transfer gas supply unit 35 via the gas supply pipe 36 and the gas introduction holes 101, 102, and 103 enhances the heat transfer between the wafer W and the electrostatic chuck 25 and the heat transfer between the edge ring ER and the electrostatic chuck 25.

The shower head 24 on the ceiling has an electrode plate 37 having a large number of gas holes 37a and an electrode support 38 that supports the electrode plate 37. In addition, a buffer chamber 39 is provided inside the electrode support 38, and a gas supply pipe 41 from a processing gas supply unit 40 is connected to a gas introduction hole 38a of the buffer chamber 39.

When, for example, a dry etching process is to be performed in the substrate processing apparatus 100, first, the gate valve 20 is opened, and the wafer W is loaded into the chamber 10 and mounted on the electrostatic chuck 25. Then, for example, a gas mixture containing C₄F₈ gas, O₂ gas, and Ar gas with a predetermined flow rate ratio is introduced into the chamber 10 as a processing gas from the processing gas supply unit 40, and the pressure of the inside of the chamber 10 is set to a predetermined value by the exhaust device 18. In addition, a DC voltage is applied from the DC power supply 26 to the electrode plate 25c, and a DC voltage is applied from the DC power supplies 28 and 29 to the electrode plates 25d and 25e, so that the wafer W and the edge ring ER are electrostatically attracted on the electrostatic chuck 25. Then, a radio frequency power is supplied to the susceptor 11 from the radio frequency power supplies 21-1 and 21-2. Accordingly, the processing gas introduced through the shower head 24 is turned into plasma, and the surface of the wafer W is etched by radicals and ions contained in this plasma.

<Positional Relationship Between Electrostatic Chuck, Edge Ring, and Wafer>

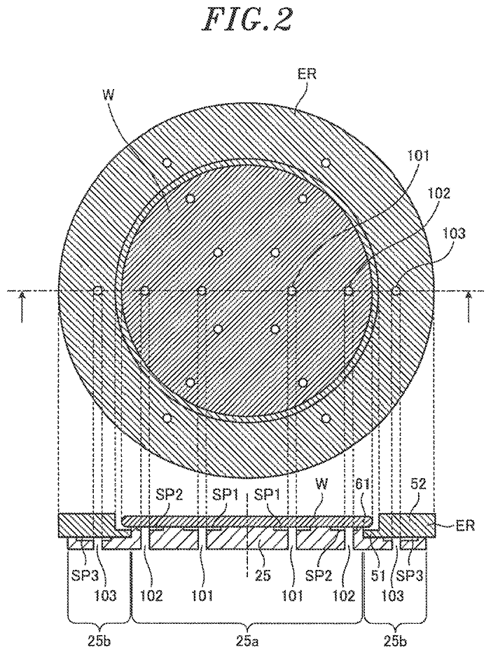

In FIG. 2, the edge ring ER has an annular shape, and an inner peripheral portion 51 of the edge ring ER is formed to be thinner than an outer peripheral portion 52 of the edge ring ER. In addition, the outer peripheral portion 25b of the electrostatic chuck 25 is formed to be thinner than the central portion 25a of the electrostatic chuck 25. The edge ring ER is mounted on the outer peripheral portion 25b of the electrostatic chuck 25, and the wafer W is mounted on the central portion 25a of the electrostatic chuck 25. In an example, the inner peripheral portion 51 of the edge ring ER is formed so that the upper surface of the inner peripheral portion 51 of the edge ring ER is lower than the upper surface of the central portion 25a of the electrostatic chuck 25. In addition, in an example, the outer peripheral portion 52 of the edge ring ER is formed so that the upper surface of the outer peripheral portion 52 of the edge ring ER has substantially the same height as the upper surface of the wafer W or is higher than the upper surface of the wafer W. In addition, the wafer W has a disc shape, and the diameter of the wafer W is larger than the diameter of the central portion 25a of the electrostatic chuck 25. Therefore, when the wafer W is mounted on the central portion 25a of the electrostatic chuck 25, a peripheral edge portion 61 of the wafer W projects outwards from the central portion 25a of the electrostatic chuck 25, and the lower surface of the peripheral edge portion 61 of the wafer W and the upper surface of the inner peripheral portion 51 of the edge ring ER face each other.

In addition, for example, six gas introduction holes 101 and six gas introduction holes 102 are provided in the central portion 25a of the electrostatic chuck 25, and, for example, six gas introduction holes 103 are provided in the outer peripheral portion 25b of the electrostatic chuck 25. The heat transfer gas is introduced into a space between the upper surface of the central portion 25a of the electrostatic chuck 25 and the lower surface of the wafer W through the gas introduction holes 101 and 102, and the heat transfer gas is introduced into a space between the upper surface of the outer peripheral portion 25b of the electrostatic chuck 25 and the lower surface of the outer peripheral portion 52 of the edge ring ER through the gas introduction holes 103.

<Configuration of Edge Ring>

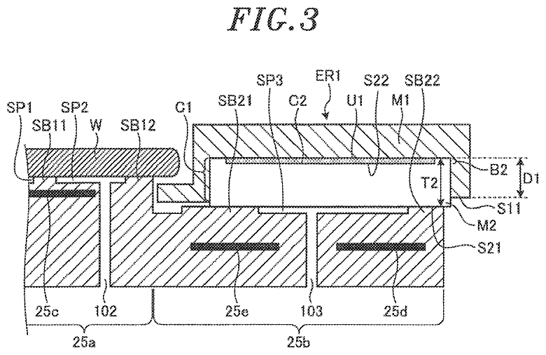

FIG. 3 is a diagram illustrating a configuration example of the edge ring. An edge ring ER1 illustrated in FIG. 3 corresponds to the edge ring ER illustrated in FIGS. 1 and 2.

In FIG. 3, the edge ring ER1 is formed by joining an annular member M1 and an annular member M2 via an adhesive layer B2. The member M1 is made of a first material having plasma resistance, and the member M2 is made of a second material having a rigidity lower than that of the first material. In other words, the second material constituting the member M2 is more flexible than the first material constituting the member M1. Example of the first material constituting the member M1 include silicon carbide, tungsten carbide (WC), magnesium oxide (MgO), or yttria (Y₂O₃). In addition, example of the second material constituting the member M2 can be silicon.

The member M1 has a recess C1 in a lower surface S11 of the member M1, and the member M2 is arranged in the recess C1 of the member M1.

A thickness T2 of the member M2 is, for example, larger than a depth Dl of the recess C1. In this case, since a lower surface S21 of the member M2 projects towards the electrostatic chuck 25 side further than the lower surface S11 of the member M1, only the member M2 out of the members M1 and M2 is in contact with the upper surface of the outer peripheral portion 25b of the electrostatic chuck 25. As a result, the adhesion of the edge ring ER1 to the electrostatic chuck 25 is further improved when the edge ring ER1 is electrostatically attracted to the electrostatic chuck 25.

The adhesive layer B2 is provided between a bottom surface U1 of the recess C1 and an upper surface S22 of the member M2. In addition, a recess C2 having a depth of, for example, about 40 μm is formed on the upper surface S22 of the member M2, and the adhesive layer B2 is provided in the recess C2 formed on the upper surface S22 of the member M2. The adhesive layer B2 includes, for example, a silicone-based adhesive.

The adhesive layer B2 may further include a conductive filler. The adhesive layer B2 containing the conductive filler improves the thermal conductivity between the member M1 and the member M2. One example of the conductive filler includes alumina.

Seal bands SB11 and SB12, each of which has an annular convex shape and is provided in the central portion 25a of the electrostatic chuck 25, support the wafer W on the central portion 25a. Thus, a space SP1 corresponding to the height of the seal bands SB11 and SB12 is formed between the upper surface of the central portion 25a and the lower surface of the wafer W. The space SP1 is connected to the gas introduction hole 102. Then, heat transfer gas supplied from the heat transfer gas supply unit 35 is introduced into the space SP1 through the gas introduction hole 102.

In addition, seal bands SB21 and SB22, each of which has an annular convex shape, are provided in the outer peripheral portion 25b of the electrostatic chuck 25. Thus, the edge ring ER1 is supported on the outer peripheral portion 25b by the seal bands SB21 and SB22. Then, a space SP2 corresponding to the height of the seal bands SB21 and SB22 is formed between the upper surface of the outer peripheral portion 25b and the lower surface S21 of the member M2. The space SP2 is connected to the gas introduction hole 103. The heat transfer gas supplied from the heat transfer gas supply unit 35 is introduced into the space SP2 through the gas introduction hole 103.

In addition, in the above-described embodiment, a case where the member M1 and the member M2 are joined via the adhesive layer B2 is described as an example, but the member M1 and the member M2 may be joined by diffusion joining.

As described above, the edge ring (edge ring ER1) according to the disclosure has the annular first member (member M1) made of the first material having plasma resistance and the annular second member (member M2) made of the second material having a rigidity lower than that of the first material. The second member is arranged in a recess (recess C1) formed on the lower surface of the first member.

In the edge ring according to the disclosure, since the first member exposed to the plasma during the plasma processing is made of the first material having the plasma resistance, the edge ring may have the plasma resistance. In addition, since the second member that is in contact with the electrostatic chuck is made of the second material having a rigidity lower than that of the first material (that is, having a flexibility higher than that of the first material), it is possible to improve the adhesion between the edge ring and the electrostatic chuck. Therefore, the edge ring according to the disclosure makes it possible to reduce the frequency of replacement of the edge ring and suppress the leakage of the heat transfer gas.

Heretofore, although the edge ring and the substrate processing apparatus are described by the above-described embodiment, the edge ring and the substrate processing apparatus according to the disclosure are not limited to the above-described embodiment, and various modifications and improvements can be made within the scope of the disclosure.

For example, the edge ring according to the disclosure can be applied not only to a capacitively coupled plasma (CCP) apparatus but also to other substrate processing apparatuses. Other substrate processing apparatuses include an inductively coupled plasma (ICP) processing apparatus, a plasma processing apparatus using a radial line slot antenna, a helicon wave excitation type plasma (helicon wave plasma (HWP)) apparatus, an electron cyclotron resonance plasma (ECR) apparatus or the like.

In addition, in the substrate processing apparatus 100 according to the present embodiment, two electrode plates for electrostatic attraction are provided in the outer peripheral portion 25b of the electrostatic chuck 25. However, the number of electrode plates provided in the outer peripheral portion 25b for electrostatic attraction may be, for example, one or may be three or more.

In this specification, the semiconductor substrate is described as the target of the plasma processing, but the target of the plasma processing is not limited to the semiconductor substrate. The target of the plasma processing may be various substrates used for an liquid crystal display (LCD), a flat panel display (FPD), or the like, a photomask, a CD substrate, a printed circuit board, or the like.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

What is claimed is:

1. An edge ring arranged around a substrate, the edge ring comprising:
an annular first member that has a recess on a lower surface and is made of a first material having plasma resistance; and
an annular second member that is arranged in the recess and is made of a second material having a rigidity lower than that of the first material.

2. The edge ring according to claim 1,
wherein the first material includes silicon carbide, tungsten carbide, magnesium oxide, or yttria, and
wherein the second material includes silicon.

3. The edge ring according to claim 1, wherein a thickness of the second member is larger than a depth of the recess.

4. The edge ring according to claim 1, wherein the first member and the second member are joined via an adhesive layer provided between a bottom surface of the recess and an upper surface of the second member.

5. The edge ring according to claim 4, wherein the adhesive layer contains a silicone-based adhesive.

6. The edge ring according to claim 4, wherein the adhesive layer further contains a conductive filler.

7. The edge ring according to claim 4, wherein the adhesive layer is provided in the recess formed on an upper surface of the second member.

8. An apparatus comprising:
a processing container which provides a processing space;
a stage which is provided inside the processing container and on which a substrate is mounted; and
an edge ring arranged so as to surround a periphery of the substrate,
wherein the stage comprises an electrode that electrostatically attracts the edge ring in a region that at least partially overlaps with the edge ring in plan view, and
wherein the edge ring includes:
an annular first member that has a recess on a lower surface and is made of a first material having plasma resistance; and
an annular second member that is arranged in the recess and that is made of a second material having a rigidity lower than that of the first material and that has a lower surface that is in contact with an upper surface of the stage.

9. The apparatus according to claim 8, further comprising a space to which a heat transfer gas is supplied between the upper surface of the stage and the lower surface of the second member.

10. The apparatus according to claim 9, wherein the stage has an introduction hole for introducing the heat transfer gas into the space, and the electrodes are two electrodes arranged with the introduction hole interposed therebetween.

11. The apparatus according to claim 8, wherein only the second member out of the first member and the second member is in contact with the upper surface of the stage.
